(19) United States
(12) Patent Application Publication
(10) Pub. No.: US 2014/0142875 A1
(43) Pub. Date: May 22, 2014

(54) APPLIANCE OPERATION STATE DETECTION

(71) Applicant: GENERAL ELECTRIC COMPANY, Schenectady, NY (US)

(72) Inventor: William Jerome Burke, Louisville, KY (US)

(73) Assignee: GENERAL ELECTRIC COMPANY, Schenectady, NY (US)

(21) Appl. No.: 13/679,069

(22) Filed: Nov. 16, 2012

(51) Int. Cl. G01R 22/10; G06F 19/00

(52) U.S. Cl. CPC G01R 22/10; G06F 19/00
USPC 702/60

(57) ABSTRACT

A system and method of identifying an operational state change in an appliance is provided. Power consumption can be measured using a power consumption measuring device such as a utility meter. The power consumption signal can be filtered by applying a filter to the power consumption signal. An initiation of a change in an operational state of the appliance can be detected. When an initiation of a change in the operational state is detected, at least one derivative of the filtered power consumption signal can be determined and compared to a predetermined threshold. When the derivative of the filtered power consumption signal exceeds the predetermined threshold, an achievement of the operational state change can be identified. An achievement of an operational state change can alternatively be identified when a counter increment exceeds a threshold.

### FIELD OF THE INVENTION

The present disclosure relates to a home appliance and more particularly to an improved method of detecting an achieved operational state of the home appliance based on a detected initiation of a change in operational state of the appliance.

### BACKGROUND OF THE INVENTION

The increasing demand for energy and the use of finite resources for energy production have led to the use of increased technology for the production, transmission, distribution, and consumption of energy in order to make, distribute and use energy more efficiently and wisely. Previously, a utility charged a flat rate for power consumption. However, as energy prices increase and energy use fluctuates throughout the day, utilities have become more sophisticated with regard to variable rates relating to the energy supplied to customers.

Power consumption, and more particularly power consumption of household consumer appliances at a location, is generally measured using a utility usage meter. Utility usage meters are limited to monitoring the overall power consumption at a single location. Meters measure the power consumption for the entire premises and are unable to distinguish the power consumption for each individual appliance within the premises. Power consumption within an appliance can be related to the current operational state in which the appliance is operating. For instance, in a HVAC system, there can be a delay between when a thermostat requests a change in an operational state and when a controller actuates the change in operational state. This delay can be unpredictable and can cause inaccuracies in energy estimation and prediction.

Thus, a need exists for an improved energy management system. A system and method of controlling an appliance based on an achieved change in operational state of the appliance would be particularly useful.

### BRIEF DESCRIPTION OF THE INVENTION

Aspects and advantages of the invention will be set forth in part in the following description, or may be apparent from the description, or may be learned through practice of the invention.

One exemplary aspect of the present disclosure is directed to a computer-implemented method of identifying an operational state of an appliance. The method can include receiving a power consumption signal indicative of power consumption; applying a filter (e.g. a Gaussian filter) to the power consumption signal to generate a filtered power signal; and detecting an initiation of change in operation state of the appliance. The method can further include determining a derivative of the filtered power consumption signal and comparing the derivative of the filtered power consumption signal to a predetermined threshold. The method can further include identifying an achieved operational state change of the appliance when the derivative of the filtered power consumption signal falls outside the predetermined threshold.

Another exemplary aspect of the present disclosure is directed to a controller coupled to an appliance. The controller is configured to execute computer readable instruction to cause a processor to: receive a power consumption signal indicative of power consumption; apply a filter (e.g. a Gaussian filter) to the power consumption signal to generate a filtered power consumption signal; detect a signal indicative of an initiation of change in operational state of the appliance; determine a derivative of the filtered power consumption signal; compare the derivative of the filtered power consumption signal to a predetermined threshold; and identify an achieved operational state change of the appliance when the derivative of the filtered power consumption signal falls outside the predetermined threshold.

Yet another exemplary aspect of the present disclosure is directed to a system of identifying an operational state of an appliance installed on a premises. The system includes an appliance configured to consume power and a controller. The controller is configured to receive a power consumption signal indicative of power consumption for the premises; apply a filter (e.g. a Gaussian filter) to the power consumption signal to generate a filtered power consumption signal; detect an initiation of change in operational state of the appliance; determine a derivative of the filtered power consumption signal; compare the derivative of the filtered power consumption signal to a predetermined threshold, and identify an achieved operational state change of the appliance when the derivative of the filtered power consumption signal falls outside the predetermined threshold.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 depicts a block diagram of a system for identifying an operational state of an appliance according to an exemplary embodiment of the present disclosure;

FIG. 2 depicts a block diagram of a system for identifying an operational state of an appliance according to an exemplary embodiment of the present disclosure;

FIG. 3 depicts a flow chart of a method according to an exemplary embodiment of the present disclosure; and

FIG. 4 depicts a flow chart of a method according to an exemplary embodiment of the present disclosure.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

Generally, the present disclosure relates to a system and method of identifying an operational state change in an appliance. Power consumption can be measured using a power consumption measuring device such as a utility meter. The power consumption signal can be indicative of power consumption of the appliance, of a subset of appliances, or power consumption of an entire premises. The power consumption signal can be filtered by applying a filter (e.g. a Gaussian filter or other suitable filter) to the power consumption signal. An initiation of a change in an operational state of the appliance can be detected. An operational state can include various speeds, and/or power levels, such as on-off, low, medium, and high, temperatures, etc. When an initiation of a change in the operational state is detected, at least one derivative of the filtered power consumption signal can be determined and compared to a predetermined threshold. When the derivative of the filtered power consumption signal exceeds the predetermined threshold, an achievement of the operational state change can be identified. An achievement of an operational state change can alternatively be identified when a counter increment exceeds a threshold.

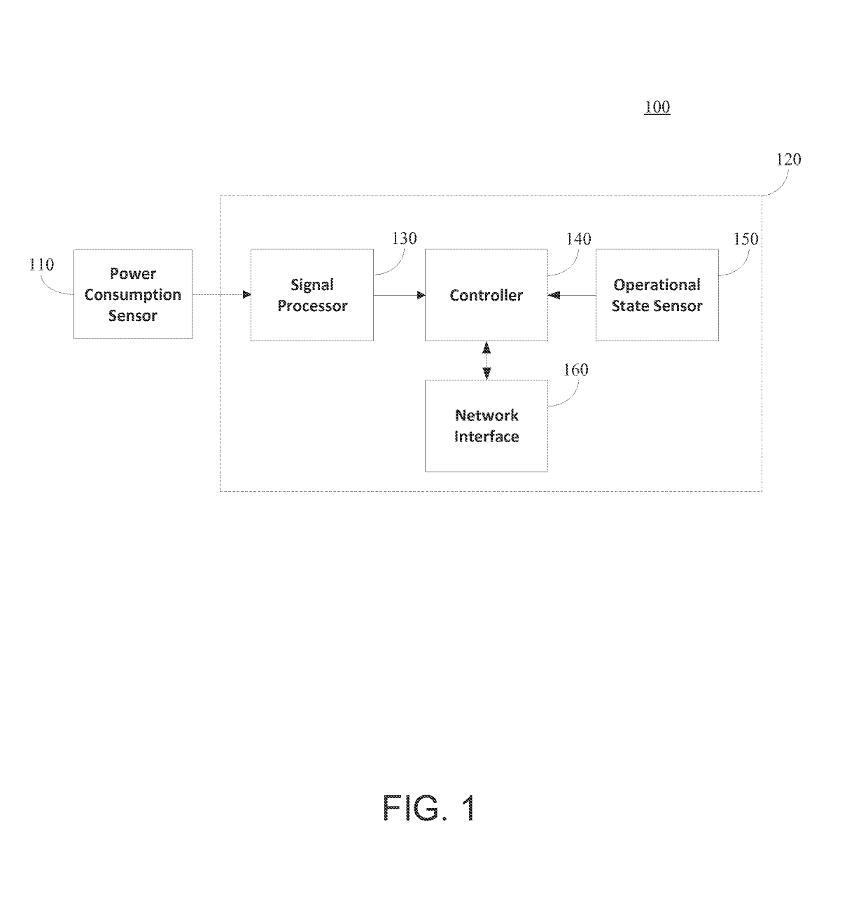

FIG. 1 illustrates an exemplary system 100 for identifying an operational state of an appliance according to an exemplary embodiment of the present disclosure. The system 100 can be located at a premises such as a residential, commercial, or industrial premises. In addition, the system 100 can include a power consumption sensor 110, an appliance 120, a signal processor 130, a controller 140, an operational state sensor 150, and a network interface 160. Network interface 160 can be used to connect the appliance 120 to a communication network.

Power consumption sensor 110 can be any type of sensor configured to detect power consumption. The power consumption sensor 110 can detect power consumption of the appliance, a subset of a plurality of appliances, or power consumption for an entire premises. For example, power consumption sensor 110 can be a utility meter, such as an analog or digital electric meter, configured to measure the power consumed at a premises.

Power consumption sensor 110 can be coupled to a signal processor 130 within an appliance 120 to provide a signal to the appliance 120 indicative of power consumption. Appliance 120 can be any home appliance used on the premises such as a HVAC system, a refrigerator, a washer, a dryer, an oven, a cooktop, and a range.

The signal processor 130 can apply a Gaussian filter to the power consumption signal to produce a filtered power consumption signal. The Gaussian filter can be a signal processing filter that has a characteristic approximate to a bell curve shape where the edges of the filter fall toward plus and minus infinity. Signal processor 130 can include parameters associated with the height of the curve's peak, the position of the center of the peak, and the width of the “bell”. The parameters of the Gaussian filter can be adjusted and modified. Signal processor 130 can be separate from controller 140 as illustrated. Alternatively, signal processor 130 can be included within controller 140.

Controller 140 can identify that a change in operational state of the appliance has been achieved based on the filtered power consumption signal. An operational state can include various speeds and/or power levels, such as on-off, low, medium, and high, temperatures, etc. After identifying that a change in operational state of the appliance has been achieved, this information can be used in various power consumption and energy saving techniques. For instance, the controller can perform sub-metering calculations to determine the power consumption of the appliance based on the information regarding the achieved change in operational state. The controller can also provide the achieved operational state change information to a remote device such as a home energy manager using the network interface 160 where the remote device can calculate power consumption information for the appliance or premises power consumption. In another implementation, the controller 140 can use the achieved operational state change information to control the appliance 120.

Controller 140 can be positioned in any location within the appliance 120. In addition, controller 140 can be the only controller in the appliance 120 such that controller 120 controls all operations of the appliance. Alternatively, controller 120 can be a sub-controller coupled to the overall appliance controller. If controller 120 is a sub-controller, it can be located with the overall appliance controller or be separate from the overall appliance controller.

By way of example, any/all of the “controllers” and “processors” discussed in this disclosure can include a memory and one or more processing devices such as microprocessors, CPUs or the like, such as general or special purpose microprocessors operable to execute programming instructions or micro-control code associated with operation of an appliance 120. For instance, the controller 140 can include a non-transitory, computer readable medium having computer readable instructions configured to be executed by a processor to cause the processor to perform operations. The memory can represent random access memory such as DRAM, or read only memory such as ROM or FLASH. In one embodiment, the processor executes programming instructions stored in memory. The memory can be a separate component from the processor or can be included onboard within the processor. Alternatively, the controller might also be constructed without using a microprocessor, using a combination of discrete analog and/or digital logic circuitry (such as switches, amplifiers, integrators, comparators, flip-flops, AND gates, and the like) to perform control functionality instead of relying upon software.

In a particular embodiment of the present disclosure, the controller 140 can monitor for an initiation of change in operational state of the appliance 120 based on a signal from the operational state sensor 150. Operational state sensor 150 can detect an initiation of change in the current operational state of the appliance 120 in various ways. For instance, when the appliance is an HVAC system, the operational state sensor 150 can detect the initiation of change in operational state of a thermostat relay. In a refrigerator, the operational state sensor 150 can detect an initiation of change in operational state of the compressor.

The signal processor 130 can provide the filtered power consumption signal to the controller. When the controller 140 receives a signal indicative of the initiation of change in operational state from the operational state sensor 150, at least one derivative of the filtered power consumption signal can be determined. For instance, a first derivative of the filtered power consumption signal can be determined. Alternatively, a first and second derivative of the filtered power consumption signal could be determined.

Controller 140 can then compare the first derivative or the first and second derivatives of the filtered power consumption signal to a predetermined threshold. The predetermined threshold can be a single value or a range of values. When one or more of the derivatives of the filtered power consumption signal do not meet the predetermined threshold, the controller 140 can determine and identify that the change in operational state has been achieved. For instance, the derivatives of the filtered power consumption signal can exceed the predetermined threshold, fall below the predetermined threshold, or in the case where the predetermined threshold is a range of values, the filtered signal can be within or outside the predetermined threshold.

When one or more of the derivatives of the filtered power consumption signal are within the predetermined threshold, a counter can be incremented to monitor the number of times the derivatives of the filtered power consumption signal are compared to the threshold. The counter can be compared with a predetermined counter threshold, and if the counter integral exceeds the counter threshold, the controller can identify that the operational state change has been achieved even though it was not directly detected. If the counter does not exceed the counter threshold, the controller returns to monitoring for an updated filtered power consumption signal.

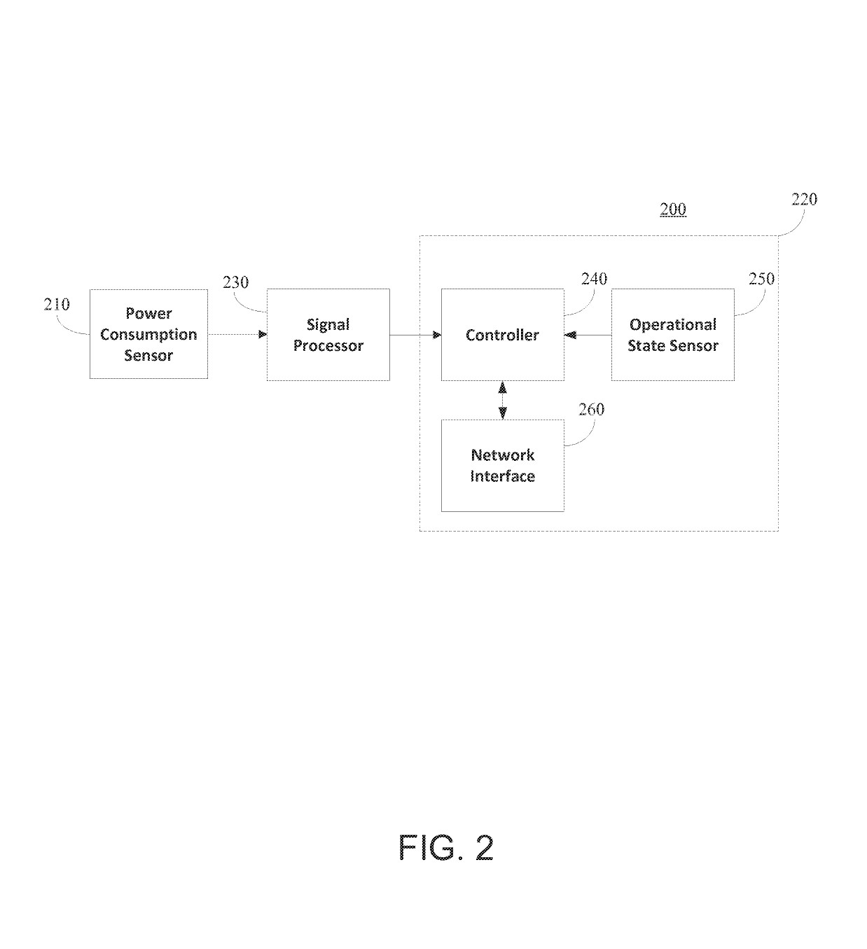

FIG. 2 illustrates an exemplary system 200 for identifying an operational state of an appliance according to an exemplary embodiment of the present disclosure. System 200 can include a power consumption sensor 210 to detect power consumed, a signal processor 203 to process a signal indicative of power consumed, and an appliance 220 including a controller 240, an operational state sensor 250 and a network interface 260. System 200 is similar to system 100 illustrated in FIG. 1, however in system 200 the signal processor 230 is separate from appliance 220 and coupled between utility meter 210 and appliance 220. For instance, the signal processor 230 can be included in a home energy management system. Signal processor 230 can apply a Gaussian filter to a signal indicative of power consumption. A filtered power consumption signal can be provided to controller 240 from the signal processor 230 and the controller 240 can identify a change in operational state of the appliance 220 based on the filtered power consumption signal.

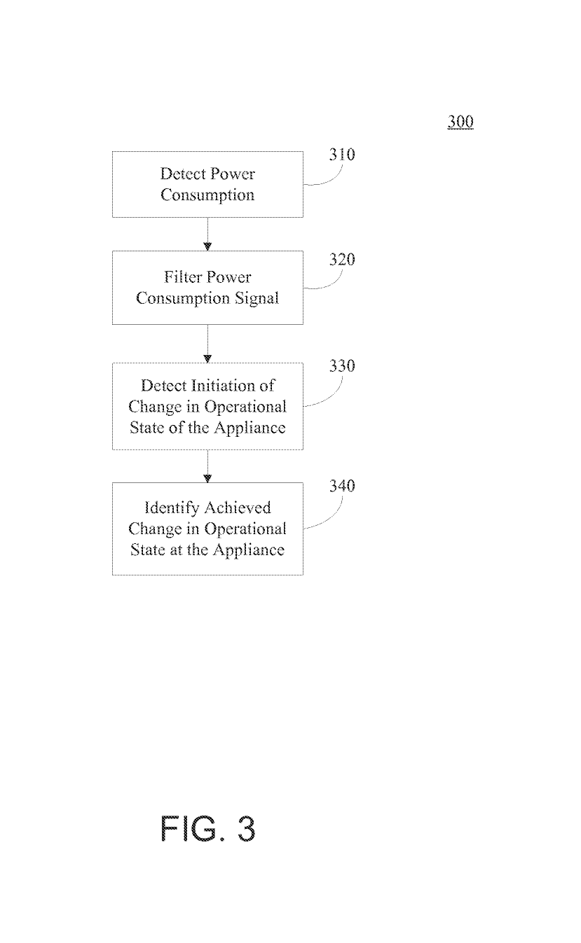

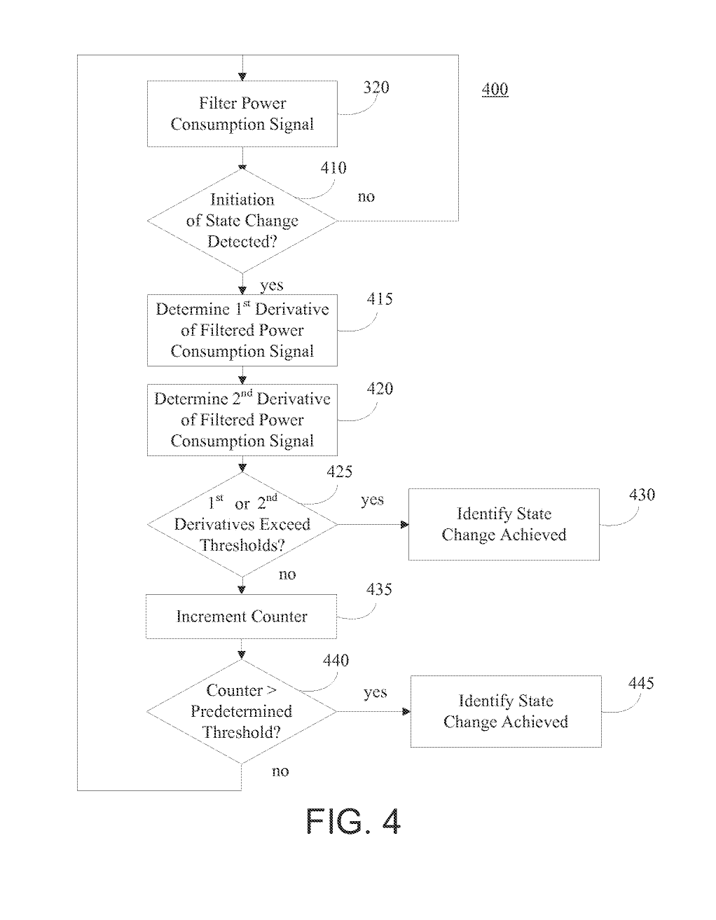

FIGS. 3 and 4 illustrate a flow chart of exemplary methods 300 and 400 according to exemplary embodiments of the present disclosure. The methods 300 and 400 can be implemented with any suitable home appliance system, such as the systems illustrated in FIG. 1 or 2. In addition, although FIGS. 3 and 4 depict steps performed in a particular order for purposes of illustration and discussion, the methods discussed herein are not limited to any particular order or arrangement. One skilled in the art, using the disclosures provided herein, will appreciate that various steps of the methods can be omitted, rearranged, combined and/or adapted in various ways.

FIG. 3 provides a flow chart of an exemplary method 300 of determining appliance power consumption according to an exemplary embodiment of the present disclosure. A power consumption sensor can detect power consumption of an appliance, a subset of appliances, or an entire premises in (310) and provide a signal indicative of the detected power consumption to a signal processor. The signal processor can apply a Gaussian filter to the signal indicative of power consumption at (320). n initiation of change in operational state of the appliance can be detected by an operational state sensor at (330). In (340), an identification that the appliance has achieved the change in operational state can be determined. An exemplary technique for identifying a change in operational state of the appliance will be discussed with respect to FIG. 4.

FIG. 4 provides a flow chart of an exemplary method 400 of identifying a change in operational state of the appliance according to an exemplary embodiment of the present disclosure. At (320) a signal indicative of power consumption at a premises can be filtered using a Gaussian filter. At (410), a determination can be made whether an initiation of a change in operational state of the appliance is detected. When an initiation of a state change is detected, a first derivative of the filtered power consumption signal can be determined at (415) and a second derivative of the filtered power consumption signal can be determined at (420). At (425), the first and/or the second derivative of the filtered power consumption signal can be compared to predetermined thresholds to determine if the derivatives exceed the thresholds. Alternatively, the first derivative of the filtered power consumption signal can be determined and compared to a predetermined threshold before determining the second derivative of the filtered power consumption signal.

When one or more of the first and second derivatives of the filtered power consumption signals exceed the threshold, an achieved operational state change can be identified at (430). If the derivatives do not exceed the threshold, a counter can be incremented at (435). When it is determined that the counter exceeds a predetermined counter threshold at (440), an achieved operational state change can be identified at (445). If the counter does not exceed the predetermined counter threshold, the controller returns to monitoring for the filtered power consumption signal at (320). As the method 400 is repeated, if another initiation of state change is detected before identifying that a state change has been achieved, the method 400 begins to identify when the achieved operational state change occurs for the new detected initiation of change in operational state.

While FIG. 4 has been illustrated as determining a first and a second derivative, an alternative technique for identifying a change in operational state of the appliance can include only determining a first derivative of the filtered power consumption signal. Alternatively, more than two derivatives of the filtered power consumption signal can be determined and compared to a predetermined range. In addition, when comparing the derivatives of the filtered power consumption signal to the predetermined range, the predetermined range can be the same for all derivatives or it can be different for one or more derivatives.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A computer-implemented method of identifying an operational state of an appliance, comprising:
receiving a power consumption signal indicative of power consumption;
applying a filter to the power consumption signal to generate a filtered power signal;
detecting an initiation of change in operational state of the appliance;
determining a derivative of the filtered power consumption signal;
comparing the derivative of the filtered power consumption signal to a predetermined threshold; and
identifying an achieved operational state change of the appliance when the derivative of the filtered power consumption signal falls outside the predetermined threshold.

2. The computer-implemented method as in claim 1, further comprising:
incrementing a counter when the derivative of the filtered power consumption signal is within the predetermined threshold; and
identifying an achieved operational state change of the appliance when the counter exceeds a predetermined counter threshold.

3. The computer-implemented method as in claim 1, wherein the power consumption signal is indicative of power consumption of the appliance, a subset of appliances including the appliance, or power consumption at a premises.

4. The computer-implemented method as in claim 1, wherein determining a derivative of the filtered power consumption signal comprises:
determining a first derivative of the filter power consumption signal; and
determining a second derivative of the filter power consumption signal.

5. The computer-implemented method as in claim 4, wherein the method comprises comparing first derivative of the filtered power consumption signal and the second derivative of the filtered power consumption signal to the predetermined threshold.

6. The computer-implemented method as in claim 5, wherein an achieved operational state change is identified when at least one of the first derivative of the filtered power consumption signal and the second derivative of the filtered power consumption signal falls outside the predetermined threshold.

7. A controller coupled to an appliance, the controller configured to execute computer readable instruction to cause a processor to perform operations, the operations comprising:
receiving a power consumption signal indicative of power consumption;
applying a filter to the power consumption signal to generate a filtered power consumption signal;
detecting a signal indicative of an initiation of change in operational state of the appliance;
determining a derivative of the filtered power consumption signal;
comparing the derivative of the filtered power consumption signal to a predetermined threshold; and
identifying an achieved operational state change of the appliance when the derivative of the filtered power consumption signal falls outside the predetermined threshold.

8. The controller as in claim 7, wherein the operations comprise:
increment a counter when the derivative of the filtered power consumption signal is within the predetermined threshold; and
identify an achieved operational state change when the counter exceeds a predetermined counter threshold.

9. The controller as in claim 7, wherein the filter is a Gaussian filter.

10. The controller as in claim 7, wherein the operation of determining a derivative of the filtered power consumption signal comprises:
determining a first derivative of the filter powered consumption signal; and
determining a second derivative of the filter powered consumption signal.

11. The controller as in claim 10, wherein the first derivative of the filtered power consumption signal and the second derivative of the filtered power consumption signal are compared to the predetermined threshold.

12. The controller as in claim 10, wherein an achieved operational state change is identified when at least one of the first derivative of the filtered power consumption signal and the second derivative of the filtered power consumption signal falls outside the predetermined threshold.

13. A system of identifying an operational state of an appliance installed on a premises, comprising:
an appliance configured to consume power; and
a controller coupled to the appliance, the controller configured to:
receive a power consumption signal indicative of power consumption,
apply a filter to the power consumption signal to generate a filtered power consumption signal,
detect an initiation of change in operational state of the appliance,
determine a derivative of the filtered power consumption signal,
compare the derivative of the filtered power consumption signal to a predetermined threshold, and
identify an achieved operational state change of the appliance when the derivative of the filtered power consumption signal falls outside the predetermined threshold.

14. The system as in claim 13, wherein the controller is further configured to increment a counter when the derivative of the filtered power consumption signal is within the predetermined threshold, and identify an achieved operational state change of the appliance when the counter exceeds a predetermined counter threshold.

15. The system as in claim 13, wherein the filter is a Gaussian filter

16. The system as in claim 13, wherein the controller is configured to determine a derivative of the filtered power signal by determining a first derivative of the filter powered consumption signal and determining a second derivative of the filter powered consumption signal.

17. The system as in claim 16, wherein the controller is configured to compare the first derivative of the filtered power consumption signal and the second derivative of the filtered power consumption signal to a predetermined threshold.

18. The system as in claim 17, wherein an achieved operational state change of the appliance is identified when at least one of the first derivative of the filtered power consumption signal and the second derivative of the filtered power consumption signal falls outside the predetermined threshold.

19. The system as in claim 13, wherein the controller is located in at least one of the appliance and a home energy management system.

20. The system as in claim 13, wherein the appliance is at least one of a HVAC system, a refrigerator, a washer, a dryer, an oven, a cooktop, and a range.
